(19) United States
(12) Patent Application Publication
(10) Pub. No.: US 2026/0291624 A1
(43) Pub. Date: Sep. 24, 2026

(54) Methods And Apparatus For Signal Design And Sequence Configuration In An Integrated Sensing And Communication System

(71) Applicants: MediaTek Singapore Pte. Ltd., Singapore (SG); Shanghai Jiao Tong University, Shanghai (CN)

(72) Inventors: Aimin Tang, Shanghai (CN); Ning Wei, Shanghai (CN); Shuhan Wang, Shanghai (CN); Wenze Qu, Beijing (CN)

(73) Assignees: MediaTek Singapore Pte. Ltd., Singapore (SG); Shanghai Jiao Tong University, Shanghai (CN)

(21) Appl. No.: 19/571,570

(22) Filed: Mar. 19, 2026

(30) Foreign Application Priority Data
Mar. 21, 2025 (WO) PCT/CN2025/084007
Sep. 17, 2025 (WO) PCT/CN2025/121938
Mar. 17, 2026 (CN) 202610329611.3

(51) Int. Cl. H04B 17/10; G01R 21/00; G06F 18/23; H04B 1/10; H04B 17/30

(52) U.S. Cl. CPC H04B 17/104; G01R 21/006; G06F 18/23; H04B 1/10; H04B 17/30

(57) ABSTRACT

Various solutions for signal design and sequence configuration in an Integrated Sensing and Communication (ISAC) system with respect to an apparatus in mobile communications are described. The apparatus may transmit one or more sensing signals. The one or more sensing signals may include a first sensing signal. The first sensing signal may include: (1) a first sequence transmitted by a first power, and (2) a second sequence transmitted by a second power. The first power may be higher than the second power.

### CROSS REFERENCE TO RELATED PATENT APPLICATION(S)

The present disclosure is part of a non-provisional application claiming the priority benefit of PCT Application No. PCT/CN2025/084007, filed 21 Mar. 2025, PCT Application No. PCT/CN2025/121938, filed 17 Sep. 2025, and CN application No. 202610329611.3, filed on 17 Mar. 2026, the contents of which herein being incorporated by reference in their entirety.

### TECHNICAL FIELD

The present disclosure is generally related to an Integrated Sensing and Communication (ISAC) system, and, more particularly, to signal design and sequence configuration in an ISAC system.

### BACKGROUND

Unless otherwise indicated herein, approaches described in this section are not prior art to the claims listed below and are not admitted as prior art by inclusion in this section.

With the advancement of Integrated Sensing and Communication (ISAC) in some network systems (e.g., 5G, Beyond 5G (B5G), and 6G networks), incorporating radar sensing into wireless networks has become increasingly important. Robust and reliable radar sensing under practical deployment constraints has become critical.

However, full-duplex sensing architectures may suffer from residual self-interference, which may obscure weak long-range echoes, while Orthogonal Frequency Division Multiplexing (OFDM)-based sensing may experience inter-symbol interference. Although pulse-based radar may avoid these issues, it may introduce a minimum detection range, and partially received echoes may generate increased sidelobes that degrade detection performance. Furthermore, mutual interference among sensing signals from different cells or base stations and receiver saturation further limit overall sensing capability.

Accordingly, improved signal design and configuration mechanisms to support reliable sensing in ISAC systems have become increasingly important. Therefore, there remains a need for enhanced signal design and configuration techniques to improve sensing reliability in ISAC systems.

### SUMMARY

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

An objective of the present disclosure is to propose solutions or schemes that address the aforementioned issues pertaining to signal design and sequence configuration in an Integrated Sensing and Communication (ISAC) system with respect to apparatus in mobile communications.

In one aspect, a method may involve an apparatus transmitting one or more sensing signals. The one or more sensing signals may include a first sensing signal. The first sensing signal may include a first sequence transmitted by a first power and a second sequence transmitted by a second power. The first power may be higher than the second power.

In one aspect, a method may involve an apparatus transmitting a plurality of sensing signals. Each sensing signal may include a first sequence. The first sequence may include a first portion of the first sequence and a second portion of the first sequence. The first sequences of the sensing signals may form a first complementary sequence set. The first portion of the first sequence and the second portion of the first sequence may be configured to suppress sidelobes of partially received signals.

In one aspect, an apparatus may comprise a transceiver which, during operation, wirelessly communicates with a wireless network. The apparatus may also comprise a processor communicatively coupled to the transceiver. The processor, during operation, may perform operations comprising receiving, via the transceiver, one or more reflections corresponding to one or more sensing signals. The one or more sensing signals may include a first sensing signal. The first sensing signal may include a first sequence transmitted by a first power and a second sequence transmitted by a second power. The first power may be higher than the second power.

It is noteworthy that, although description provided herein may be in the context of certain radio access technologies, networks and network topologies such as Long-Term Evolution (LTE), LTE-Advanced, LTE-Advanced Pro, 5th Generation (5G), New Radio (NR), Internet-of-Things (IOT) and Narrow Band Internet of Things (NB-IOT), Industrial Internet of Things (IIoT), and 6th Generation (6G), the proposed concepts, schemes and any variation(s)/derivative(s) thereof may be implemented in, for and by other types of radio access technologies, networks and network topologies. Thus, the scope of the present disclosure is not limited to the examples described herein.

### BRIEF DESCRIPTION OF THE DRAWINGS

The accompanying drawings are included to provide a further understanding of the disclosure and are incorporated in and constitute a part of the present disclosure. The drawings illustrate implementations of the disclosure and, together with the description, serve to explain the principles of the disclosure. It is appreciable that the drawings are not necessarily in scale as some components may be shown to be out of proportion than the size in actual implementation in order to clearly illustrate the concept of the present disclosure.

FIG. 1 is a diagram depicting an example scenario under schemes in accordance with implementations of the present disclosure.

FIG. 2 is a diagram depicting an example signal design under schemes in accordance with implementations of the present disclosure.

FIG. 3 is a diagram depicting an example signal design under schemes in accordance with implementations of the present disclosure.

FIG. 4 is a diagram depicting an example signal design under schemes in accordance with implementations of the present disclosure.

FIG. 5A is a diagram depicting relation between signals and symbols under schemes in accordance with implementations of the present disclosure.

FIG. 5B is a diagram depicting relation between signals and symbols under schemes in accordance with implementations of the present disclosure.

FIG. 6A is a diagram depicting relation between different symbols under schemes in accordance with implementations of the present disclosure.

FIG. 6B is a diagram depicting relation between different symbols under schemes in accordance with implementations of the present disclosure.

FIG. 7A is a diagram depicting an example sensing period under schemes in accordance with implementations of the present disclosure.

FIG. 7B is a diagram depicting an example sensing period under schemes in accordance with implementations of the present disclosure.

FIG. 8 is a diagram depicting an example sensing echo signals under schemes in accordance with implementations of the present disclosure.

FIG. 9 is a diagram depicting sensing signals under schemes in accordance with implementations of the present disclosure.

FIG. 10A is a diagram depicting sensing signals under schemes in accordance with implementations of the present disclosure.

FIG. 10B is a diagram depicting sensing signals under schemes in accordance with implementations of the present disclosure.

FIG. 11 is a diagram depicting sensing signals under schemes in accordance with implementations of the present disclosure.

FIG. 12 is a diagram depicting sensing signals under schemes in accordance with implementations of the present disclosure.

FIG. 13 is a diagram depicting sensing signal groups under schemes in accordance with implementations of the present disclosure.

FIG. 14 is a diagram depicting sensing signal groups under schemes in accordance with implementations of the present disclosure.

FIG. 15A is a diagram depicting a network node and corresponding sectors under schemes in accordance with implementations of the present disclosure.

FIG. 15B is a diagram depicting network nodes and corresponding sectors under schemes in accordance with implementations of the present disclosure.

FIG. 16 is a diagram depicting sensing architecture under schemes in accordance with implementations of the present disclosure.

FIG. 17 is a diagram depicting sensing architecture under schemes in accordance with implementations of the present disclosure.

FIG. 18 is a block diagram of an example apparatus in accordance with an implementation of the present disclosure.

FIG. 19 is a flowchart of an example process in accordance with an implementation of the present disclosure.

FIG. 20 is a flowchart of an example process in accordance with an implementation of the present disclosure.

### DETAILED DESCRIPTION OF PREFERRED IMPLEMENTATIONS

Detailed embodiments and implementations of the claimed subject matters are disclosed herein. However, it shall be understood that the disclosed embodiments and implementations are merely illustrative of the claimed subject matters which may be embodied in various forms. The present disclosure may, however, be embodied in many different forms and should not be construed as limited to the exemplary embodiments and implementations set forth herein. Rather, these exemplary embodiments and implementations are provided so that description of the present disclosure is thorough and complete and will fully convey the scope of the present disclosure to those skilled in the art. In the description below, details of well-known features and techniques may be omitted to avoid unnecessarily obscuring the presented embodiments and implementations.

### Overview

Implementations in accordance with the present disclosure relate to various techniques, methods, schemes and/or solutions pertaining to signal design and sequence configuration in an Integrated Sensing and Communication (ISAC) system with respect to apparatus in mobile communications. According to the present disclosure, a number of possible solutions may be implemented separately or jointly. That is, although these possible solutions may be described below separately, two or more of these possible solutions may be implemented in one combination or another.

In some network scenarios, an apparatus (e.g., a User Equipment (UE) or a network node) may operate as both a transmitter (TX) and a receiver (RX) to transceive signals for sensing targets and communicating with other network nodes under monostatic sensing network scenarios. In some network scenarios, an apparatus (e.g., a UE or a network node) operating as a TX and an apparatus (e.g., a UE or a network node) operating as an RX may exchange necessary network parameters. In bistatic sensing network scenarios, the TX apparatus may transmit signals for sensing targets and communicating with other network nodes and the RX apparatus may receive the signals reflected from the sensing targets.

It should be noted that the following descriptions may be provided for illustrative purposes and may focus on monostatic sensing network scenarios. However, it is not intended to be limiting. A person skilled in the art will readily appreciate that the present disclosure may also be applied to other sensing configurations, such as bistatic sensing network scenarios.

Regarding the present disclosure, in some embodiments, an apparatus (e.g., a Base Station (BS) or a UE) operated as both a TX and an RX may transmit one or more sensing signals for sensing purposes. The one or more sensing signals may include a first sensing signal. The first sensing signal may include: (1) a first sequence transmitted by a first power, and (2) a second sequence transmitted by a second power. The first power may be higher than the second power. The apparatus may receive one or more reflections corresponding to the one or more sensing signals.

Accordingly, based on the different sequences transmitted at different power levels, sensing performance for both long-range and short-range targets may be enhanced. In particular, the higher-power sequence (i.e., the first sequence) may improve detection capability for long-range targets, while the lower-power sequence (i.e., the second sequence) may reduce receiver saturation and enable reliable detection of short-range targets. Such a sensing configuration may further mitigate self-interference effects and improve overall sensing reliability.

In some embodiments, the apparatus may transmit a plurality of sensing signals. Each sensing signal may include a first sequence. The first sequence may include: (1) a first portion of the first sequence, and (2) a second portion of the first sequence. The first sequences of the sensing signals may form a first complementary sequence set. The first portion of the first sequence and the second portion of the first sequence may be configured to suppress sidelobes of partially received signals.

Accordingly, because the first sequences of the sensing signals may form the first complementary sequence set, and each first sequence may include different portions configured for partial signal processing, sidelobes generated during correlation processing, including those caused by partially received signals, may be effectively suppressed, thereby improving detection reliability and range performance.

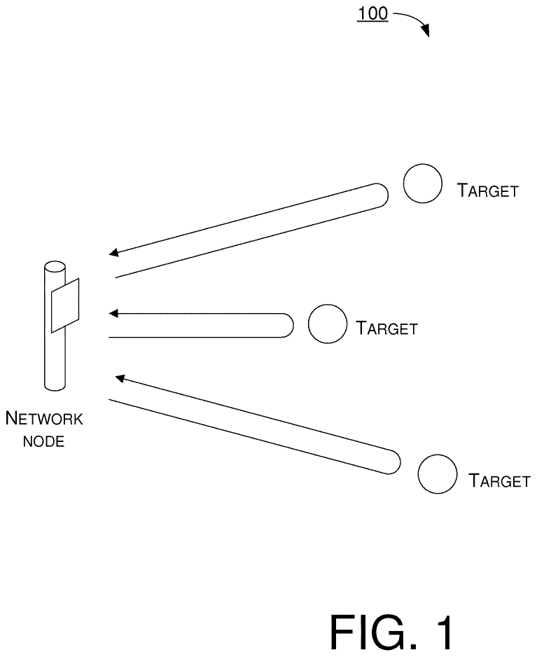

FIG. 1 illustrates an example scenario 100 under schemes in accordance with implementations of the present disclosure. Scenario 100 involves a network node and targets, which may be a part of a wireless communication network (e.g., an LTE network, a 5G/NR network, an IoT network or a 6G network).

Scenario 100 illustrates an example network framework. The network node may communicate with other devices. In the figures of the present application, the network node is exemplified as a BS for purposes of illustration in monostatic sensing network scenarios. In some cases, the BS may function as a monostatic radar, which may transmit specially designed sensing signals and receive corresponding reflection signals from the targets with a full-duplex radio. However, this example is not intended to be limiting. A person skilled in the art will readily appreciate that the network node may be implemented as other devices (e.g., a UE) and may operate in cooperation with other devices in bistatic sensing network scenarios.

In some embodiments, the network node may operate as both a TX and an RX. The network node may transmit one or more sensing signals for sensing purposes. The one or more sensing signals may include a first sensing signal. The first sensing signal may have a sequence pattern having different sequences transmitted at different power levels.

In particular, the first sensing signal may include: (1) a first sequence transmitted by a first power, and (2) a second sequence transmitted by a second power. The first power may be higher than the second power. In some cases, the first power may be configured for long-range detection. More specifically, the first power may be set to ensure sufficient transmission energy for detecting weak echoes from long-range targets. In some cases, the second power may be configured to be less than an Analog-Digital Converter (ADC) saturation power to prevent receiver saturation during the reception of echoes from short-range targets. Then, the network node may receive one or more reflections corresponding to the one or more sensing signals. The reflections may be reflected from at least one target during a receiving window.

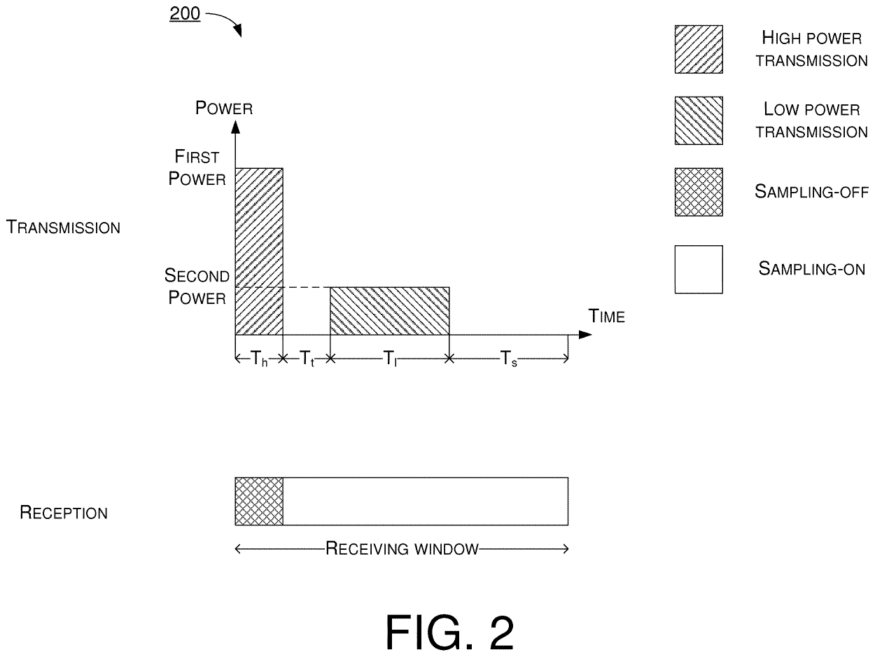

FIG. 2 illustrates an example scenario 200 under schemes in accordance with implementations of the present disclosure. In some implementations, the first sensing signal may include the first sequence and the second sequence. The first sequence may be transmitted by the first power. The second sequence may be transmitted by the second power.

In particular, a transmission of the sensing signal may be divided sequentially into multiple periods, including a high-power-level component period Tₕ, a high-low transition period Tₜ, a low-power-level component period Tₗ, and a silent period Tₛ. During the high-power-level component period, the first sequence may be transmitted at high-power-level. During the low-power-level component period, the second sequence may be transmitted at low-power-level. In some cases, the durations of the respective periods may be adjustable. In some cases, the two power levels may be configurable.

In some cases, the high-power-level component period may be used for detecting long-range targets with the high-power-level configured according to sensing requirements. In some cases, the low-power-level may be configured to be below an ADC saturation level (e.g., an ADC saturation power level at an ADC input). In some cases, the high-low transition period may be short or omitted (i.e., no high-low transition period), while the silent period may be extended to allow reception of target echoes.

In some cases, the receiving window during transmission of the sensing signal may include a sampling-off period corresponding to a period of transmitting the first sequence and a sampling-on period associated with a period of transmitting the second sequence. In some cases, during the sampling-off period, the network node may not sample incoming signals due to ADC saturation, so the network node may be in a transmit-only mode. In some cases, during the sampling-off period, the network node may sample the incoming signals but these samples may be discarded.

In some cases, the sampling-off period may have the same length as that of the high-power-level period. In some cases, during the sampling-on period, the network node may sample the incoming signals because the low-power-level may not cause the ADC to saturate, which enables the short-range detection within a blind range caused by the sampling-off period. In some cases, the sampling-on period may have the same length as the sum of the length of the high-low transition period, the low-power-level period, and the silent period. In some cases, the silent period may be zero.

In some implementations, the one or more sensing signals may include a second sensing signal. The second sensing signal may include: (1) a third sequence transmitted by the first power, and (2) a fourth sequence transmitted by the second power. The first sensing signal and the second sensing signal may be grouped based on a correlation property.

More specifically, the first sequence and the third sequence may be complementary sequences, and the second sequence and the fourth sequence may be complementary sequences.

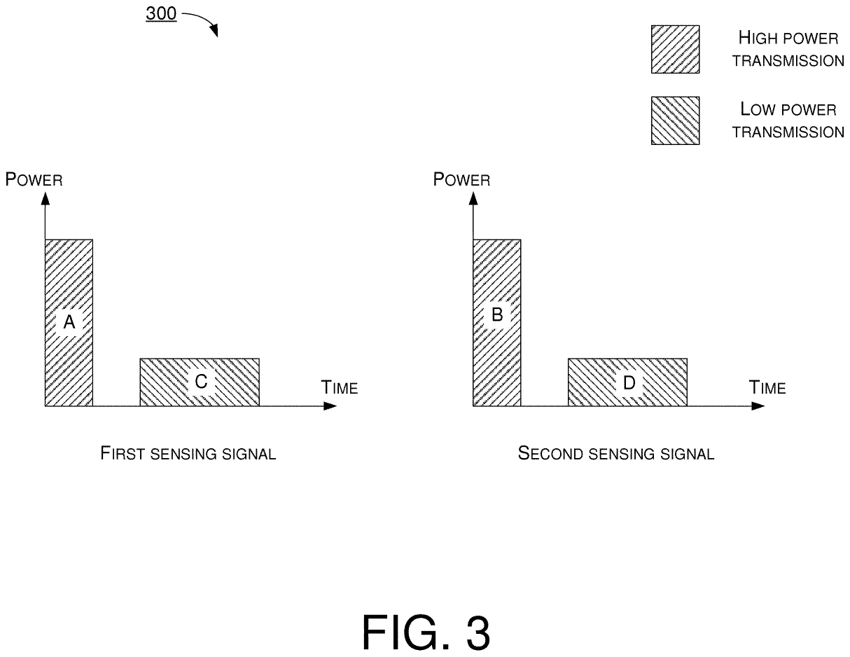

FIG. 3 illustrates an example scenario 300 under schemes in accordance with implementations of the present disclosure. In some implementations, the first sensing signal and the second sensing signal may be grouped as a signal group according to the correlation properties the signals contain. The sensing signals within one group may be jointly used for radar sensing at the network node.

In some cases, in the first sensing signal, the first sequence (i.e., sequence A) may be transmitted at the high-power-level, and the second sequence (i.e., sequence C) may be transmitted at the low-power-level. In the second sensing signal, the third sequence (i.e., sequence B) may be transmitted at the high-power-level, and the fourth sequence (i.e., sequence D) may be transmitted at the low-power-level.

In these cases, sequence A and sequence B may be configured to be complementary sequences (or approximate complementary sequences) with the same length N. Sequence C and sequence D may be configured to be complementary sequences (or approximate complementary sequences) with the same length M.

More specifically, the complementary sequences may satisfy the following equality:

$${R}_{A A} ( τ ) + {R}_{B B} ( τ ) = \{ \begin{matrix}2 N , & τ = 0 \\ 0 , & τ \neq 0\end{matrix}$$

$${R}_{C C} ( τ ) + {R}_{D D} ( τ ) = \{ \begin{matrix}2 M , & τ = 0 \\ 0 , & τ \neq 0\end{matrix}$$

$${R}_{A C} ( τ ) + {R}_{B D} ( τ ) = 0 , ∀ τ$$

where R_{xy}(τ) denotes the correlation function between sequences ‘X’ and ‘Y’ at time τ.

In addition to the requirements of complementary sequences between A and B and between C and D, additional correlation constraints may be imposed among sequences A, B, C, and D. When these complementary and correlation conditions are satisfied, range sidelobes in the overall correlation result may be eliminated when the two sensing signals are jointly processed.

In some implementations, the one or more sensing signals may include a third sensing signal and a fourth sensing signal. The third sensing signal may include: (1) a fifth sequence transmitted by the first power, and (2) a sixth sequence transmitted by the second power. The fourth sensing signal may include: (1) a seventh sequence transmitted by the first power, and (2) an eighth sequence transmitted by the second power. The first sensing signal, the second sensing signal, the third sensing signal, and the fourth sensing signal may be grouped based on the correlation property.

More specifically, the first sequence and the third sequence may be complementary sequences. In some cases, the second sequence and the fourth sequence may be complementary sequences. The fifth sequence may be the same as the first sequence. The seventh sequence may be the same as the third sequence. The sixth sequence and the second sequence may be inverse sequences. The eighth sequence and the fourth sequence may be inverse sequences. In some cases, the fifth sequence and the first sequence may be inverse sequences. The seventh sequence and the third sequence may be inverse sequences. The sixth sequence may be the same as the second sequence. The eighth sequence may be the same as the fourth sequence.

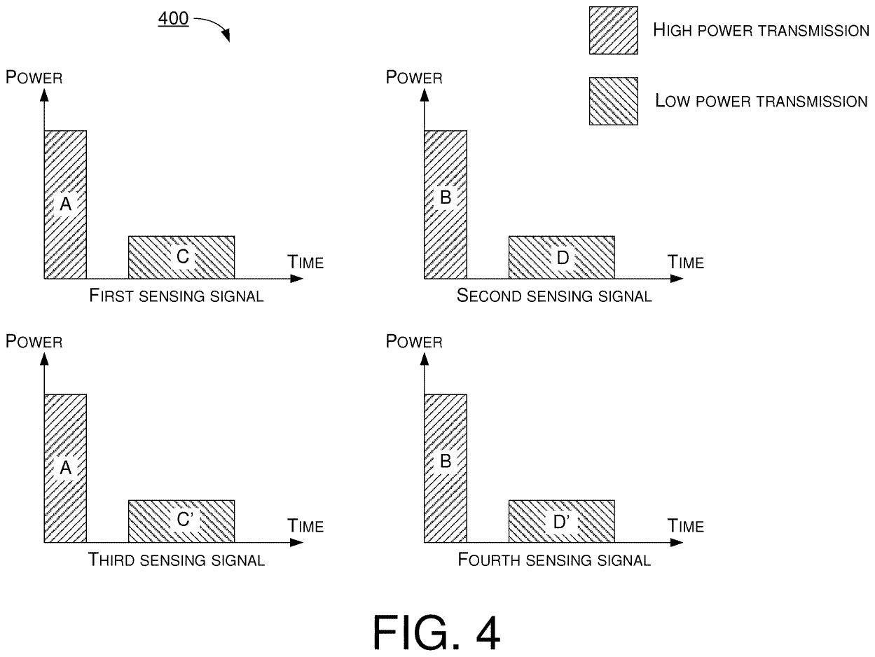

FIG. 4 illustrates an example scenario 400 under schemes in accordance with implementations of the present disclosure. In some implementations, the first sensing signal, the second sensing signal, the third sensing signal, and the fourth sensing signal may be grouped as a signal group according to the correlation properties the signals contain. The sensing signals within one group may be jointly used for radar sensing at the network node.

In some cases, in the first sensing signal, the first sequence (i.e., sequence A) may be transmitted at the high-power-level, and the second sequence (i.e., sequence C) may be transmitted at the low-power-level. In the second sensing signal, the third sequence (i.e., sequence B) may be transmitted at the high-power-level, and the fourth sequence (i.e., sequence D) may be transmitted at the low-power-level.

In some cases, in the third sensing signal, the fifth sequence (i.e., the same as sequence A) may be transmitted at the high-power-level, and the sixth sequence (i.e., sequence C′) may be transmitted at the low-power-level. In the fourth sensing signal, the seventh sequence (i.e., the same as sequence B) may be transmitted at the high-power-level, and the eighth sequence (i.e., sequence D′) may be transmitted at the low-power-level.

In these cases, sequence A and sequence C may be configured to be complementary sequences (or approximate complementary sequences) with equal length N. Sequence B and sequence D may be configured to be complementary sequences (or approximate complementary sequences) with equal length M. Sequence C and sequence C′ may be configured to be inverse sequences. Sequence D and sequence D′ may be configured to be inverse sequences.

More specifically, the complementary sequences may satisfy the following equality:

$${R}_{A A} ( τ ) + {R}_{B B} ( τ ) = \{ \begin{matrix}2 N , & τ = 0 \\ 0 , & τ \neq 0\end{matrix}$$

$${R}_{C C} ( τ ) + {R}_{D D} ( τ ) = \{ \begin{matrix}2 M , & τ = 0 \\ 0 , & τ \neq 0\end{matrix}$$

where R_{XY}(τ) denotes the correlation function between sequences ‘X’ and ‘Y’ at time τ.

In some cases, when the high-low transition period is set to zero, the overall correlation function F(τ) may be analyzed in two parts. First, when 0≤τ≤N−1,

$$F ( τ ) = 2 {R}_{A A} ( τ ) + 2 {R}_{B B} ( τ ) + {R}_{C C} ( τ ) + {R}_{D D} ( τ ) + {R}_{{C}^{′} {C}^{′}} ( τ ) + {R}_{{D}^{′} {D}^{′}} ( τ ) + {R}_{A C} ( - τ ) + {R}_{B D} ( - τ ) + {R}_{A {C}^{′}} ( - τ ) + {R}_{B {D}^{′}} ( - τ ) = \{ \begin{matrix}4 N + 4 M , & τ = 0 \\ 0 , & τ \neq 0\end{matrix}$$

Second, when N≤τ≤M+N−1,

$$F ( τ ) = {R}_{A C} ( τ ) + {R}_{B D} ( τ ) + {R}_{A {C}^{′}} ( τ ) + {R}_{B {D}^{′}} ( τ ) = 0$$

Accordingly, the overall correlation function may remain free of sidelobes even when the high-to-low transition period is non-zero.

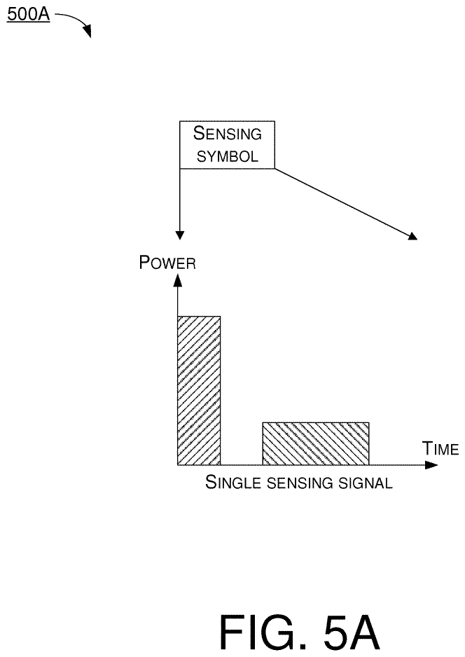

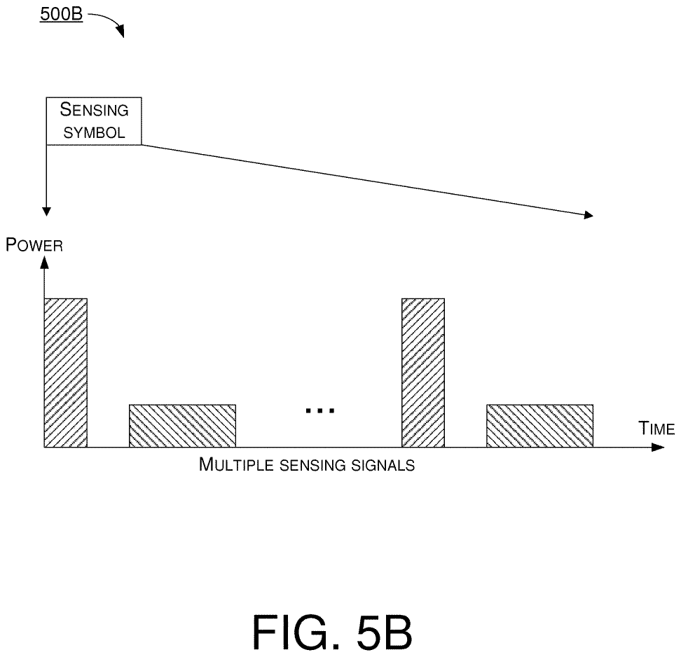

In some implementations, the one or more sensing signals may be transmitted within at least one sensing symbol. FIGS. 5A and 5B illustrate example scenarios 500A and 500B under schemes in accordance with implementations of the present disclosure. In particular, within a sensing symbol, one or more sensing signals may be arranged in various configurations. In scenario 500A, each sensing symbol may include a single sensing signal. In this case, multiple sensing symbols may be jointly processed to achieve a sidelobe-free correlation result. In scenario 500B, each sensing symbol may include multiple sensing signals. The number of sensing symbols required may depend on the number of sensing signals included in each sensing symbol, the sensing signal group adopted, and other sensing requirements.

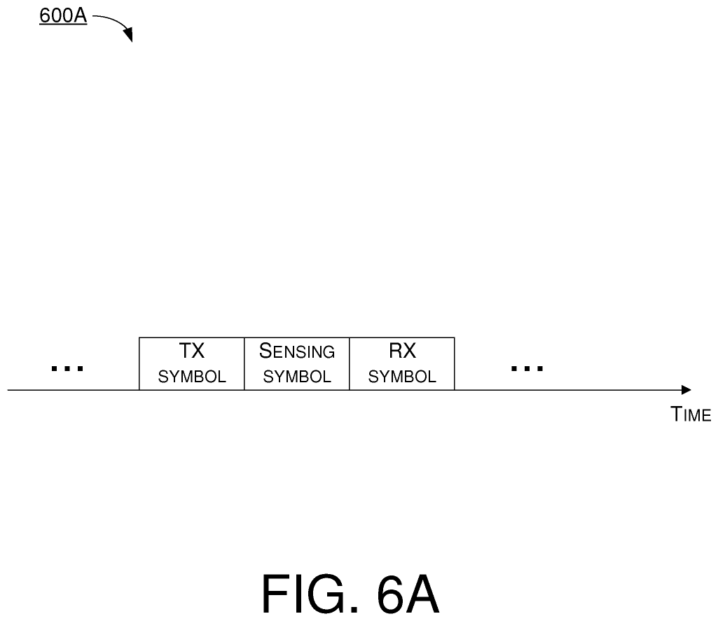

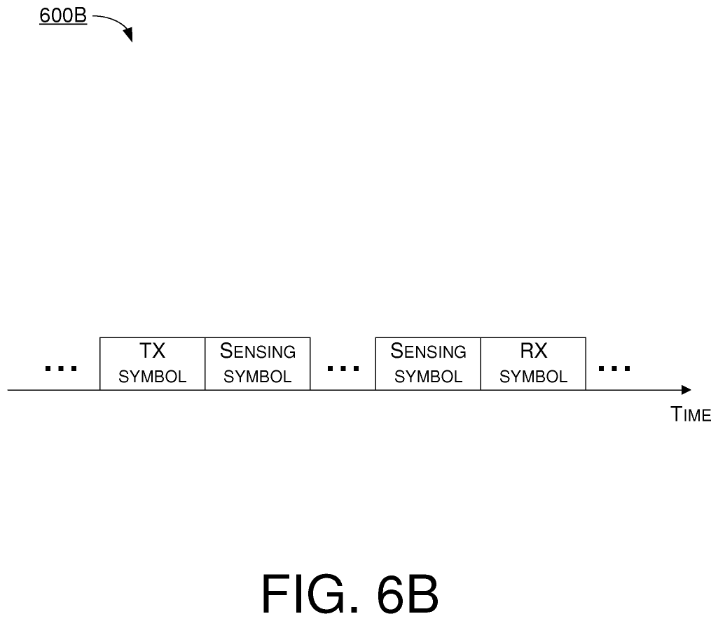

In some implementations, the at least one sensing symbol may be integrated into a TX-RX transition period. FIGS. 6A and 6B illustrate example scenarios 600A and 600B under schemes in accordance with implementations of the present disclosure. In particular, there may be a special frame with a guard interval for the network node when switching from Downlink (DL) to Uplink (UL) in a 4G network, and a flexible symbol may be required in a 5G network in the TX-RX transition period. In scenario 600A, the sensing symbol may be deployed between at least one TX symbol and at least one RX symbol. In scenario 600B, the sensing symbols may be deployed between at least one TX symbol and at least one RX symbol.

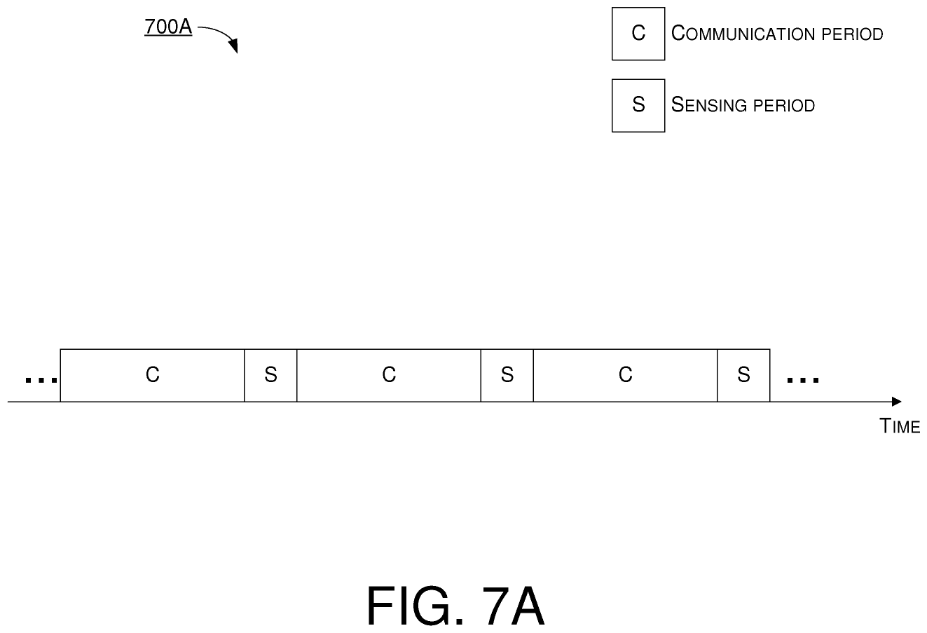

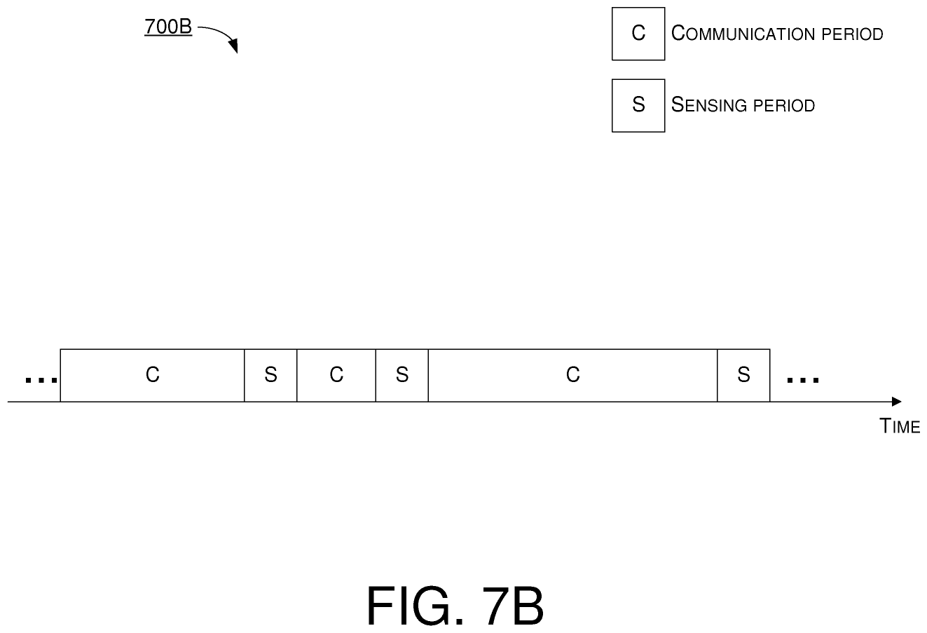

FIGS. 7A and 7B illustrate example scenarios 700A and 700B under schemes in accordance with implementations of the present disclosure. In some implementations, communication period and sensing period may appear alternatively in timeline of the network node, regardless of how many symbols are contained in the communication period and the sensing period.

In particular, TX symbols and RX symbols may constitute the communication period. Sensing symbols may constitute the sensing period. In some cases, the communication period may be longer than the sensing period. In scenario 700A, the sensing periods may be deployed periodically along the timeline, with a fixed sensing interval. In scenario 700B, the sensing periods may be deployed aperiodically along the timeline. Both scenarios may be processed to obtain sensing estimates.

The network node may process received signals during the sensing periods. The sensing signals to be jointly processed may first be sampled, and a matched filter (or a mismatched filter) may then be applied to obtain corresponding aperiodic correlation results. The outputs of the matched filtering for different sensing signals may subsequently undergo Doppler processing, for example, by applying a Fast Fourier Transform (FFT) algorithm. Constant False Alarm Rate (CFAR) detection may then be performed on the resulting delay-Doppler (RD) map to estimate the range and velocity of targets.

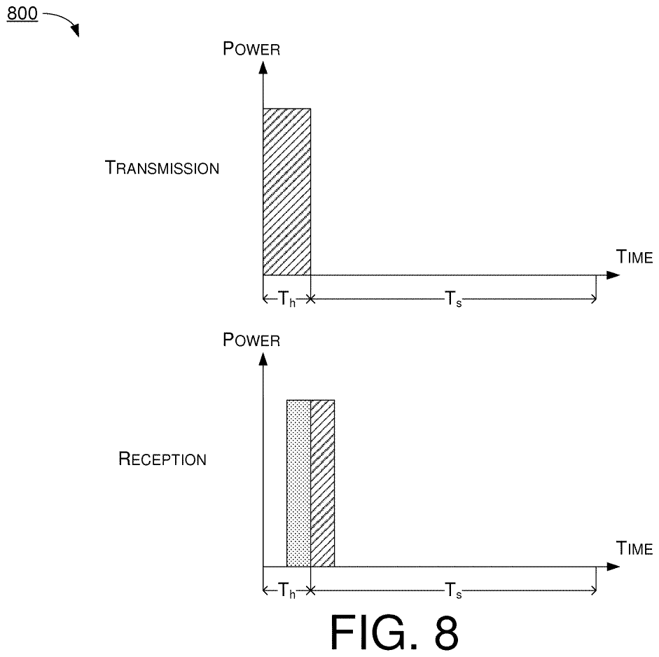

In some scenarios, partial reception of sensing echoes may occur in pulse radar systems. More specifically, as illustrated in FIG. 8, a TX of the pulse radar may be divided into two periods including: (1) a pulse transmission period Tₕ, and (2) a silent period Tₛ. The pulse transmission period may include both the radar pulse signal duration and a system recovery time required for switching from a transmission mode to a reception mode.

During the pulse transmission period, the TX may transmit a high-power continuous wave signal generated based on pulse shaping, an Orthogonal Frequency Division Multiplexing (OFDM)-based architecture, or other suitable generation methods. The generation of the continuous wave pulse signal from a sequence is not limited to these approaches. An RX of the pulse radar may operate in two different cases, depending on whether sampling is performed during transmission of the continuous wave pulse signal.

In some cases, when the RX performs sampling while the TX transmits the continuous wave pulse signal, radar echoes from targets within a minimum range may include both distorted signals caused by ADC saturation and partially received signals. During radar sensing processing, the distorted signals may be discarded. However, the partially received signals may still affect sensing operations. As a result, strong targets within the minimum range may interfere with the detection of targets outside the minimum range. Moreover, when partially received signals are used for detecting targets within the minimum range, their longer self-correlation sidelobes may degrade multi-target detection performance.

In some cases, when the RX is turned off during transmission of the continuous wave pulse signal, radar echoes from targets within the minimum range may consist solely of partially received signals. The impact of this scenario may be similar to that described in the previous case. Accordingly, an improved sequence configuration may be introduced to suppress sidelobes caused by partially received signals.

In some embodiments, the network node may transmit a plurality of sensing signals. Each sensing signal may include a first sequence. The first sequence may include: (1) a first portion of the first sequence, and (2) a second portion of the first sequence. The first sequences of the sensing signals may form a first complementary sequence set. The first portion of the first sequence and the second portion of the first sequence may be configured to suppress sidelobes of partially received signals. Then, the network node may receive one or more reflections corresponding to the sensing signals. The reflections may be reflected from at least one target during a receiving window.

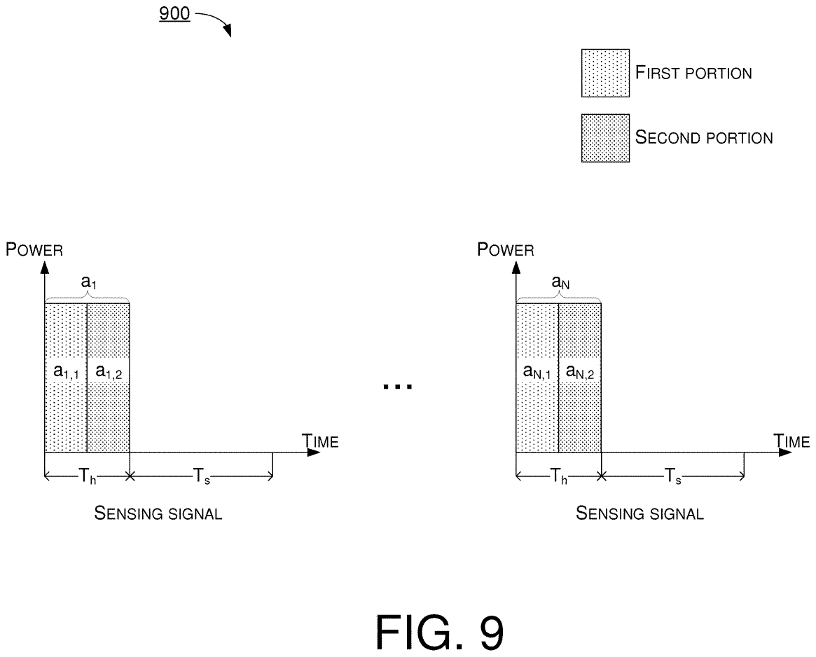

FIG. 9 illustrates an example scenario 900 under schemes in accordance with implementations of the present disclosure. In some implementations, a Sequence Set (SS) A may include N sequences of length H. Such a set may be denoted as (N, H)-SS and may be represented by an N× H matrix as:

$$A = [ \begin{matrix}{a}_{1} \\ {a}_{2} \\ ⋮ \\ {a}_{N}\end{matrix} ] .$$

where aₙ(1≤n≤N) denotes the n-th row sequence of A. a_{n,1} represents a first portion (e.g., points 1 to H/2) of sequence aₙ, and a_{n,2} represents a second portion (e.g., points H/2+1 to H) of sequence an. To suppress sidelobes of partially received signals, the network node may transmit sensing signals in groups, where each sensing signal may be implemented as a pulse. In particular, N sensing signals (i.e., pulses) (or an integer multiple of N sensing signals) may be transmitted within one coherent processing interval, such that the N sensing signal sequences may be processed as a group during coherent processing.

As shown in FIG. 9, a sensing signal group may include N sensing signals (i.e., pulses). Each transmission of one sensing signal (i.e., each pulse) may include a transmission period Tₕ and a silent period Tₛ. During the transmission period, the network node may transmit continuous signals generated from sequences for sensing purposes, where the n-th sensing signal (i.e., the n-th pulse) may correspond to transmission of sequence aₙ.

In some cases, the transmitted SS A may satisfy the following equation:

$${\sum }_{n = 1}^{N} {R}_{{a}_{n} , {a}_{n}} ( τ ) = 0 , τ \neq 0$$

where R_{α}_{ₙ}_{,α}_{ₙ}(τ) denotes an aperiodic auto-correlation function of sequence aₙ. R_{α}_{ⱼ}_{α}_{ⱼ}(τ) denotes correlation function between sequences aᵢ and aⱼ at time τ. Then A may be a complementary SS (CSS), denoted by (N×H)-CSS.

In some cases, the first portion of subsequence a_{n,1} and the second portion of subsequence a_{n,2} of sequence aₙ may satisfy the following equations:

$${\sum }_{n = 1}^{N} {R}_{{p}_{n 1} , {a}_{n , 2}} ( τ ) = 0 , ∀ τ$$

$${\sum }_{n = 1}^{N} {R}_{{a}_{n 1} , {p}_{n , 2}} ( τ ) = 0 , ∀ τ$$

where p_{n,1} denotes a partially received signal corresponding to sequence a_{n,1}, representing a portion of sequence a_{n,1} that the network node may sample. p_{n,2} denotes the partially received signal corresponding to sequence a_{n,2}. Sequences p_{n,1} and p_{n,2} may each have H/2−1 possible cases, ranging from reception of a single point of the sequence to reception of H/2−1 consecutive points of the sequence.

In some cases, through joint processing of the sensing signal group, partially received signals reflected from targets within the minimum range may not affect the detection of targets outside the minimum range. In particular, sidelobes associated with targets within the minimum range may be suppressed to remain within a range index less than H/2.

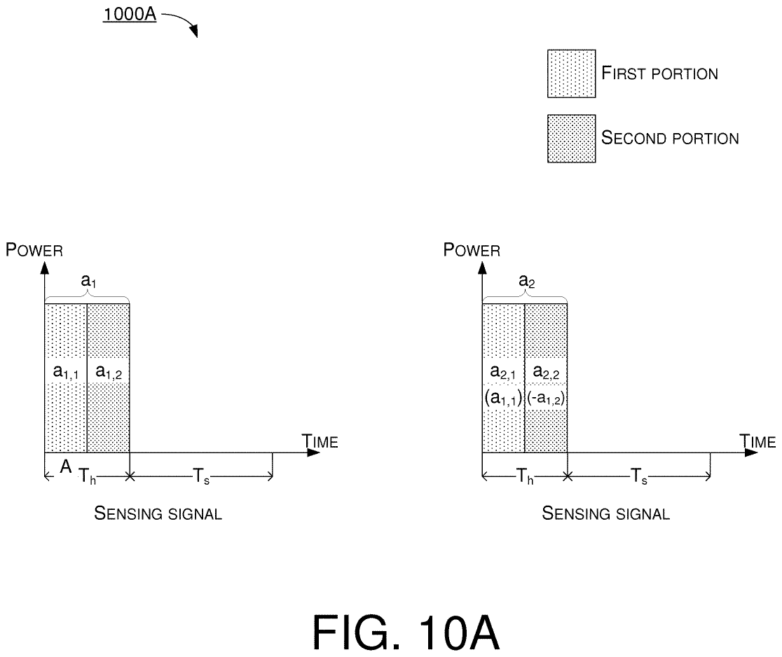

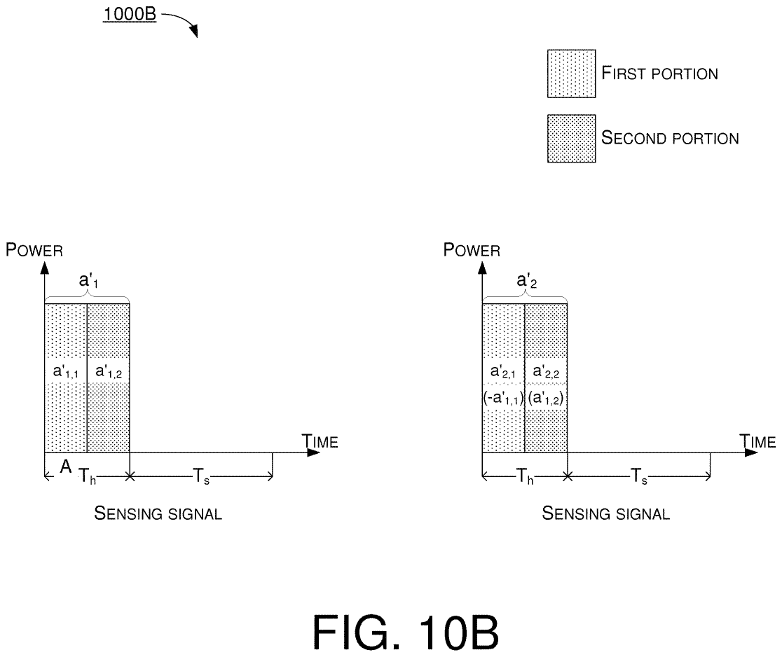

In some implementations, the plurality of sensing signals may include two sensing signals. FIGS. 10A and 10B illustrate example scenarios 1000A and 1000B under schemes in accordance with implementations of the present disclosure. In particular, the sequences of the sensing signals may require grouped transmission. The network node may transmit two sequences as a paired set.

In scenario 1000A, a sensing signal group may include a first sensing signal and a second sensing signal transmitted in pairs. A transmission of each sensing signal may be divided into a transmission period Tₕ and a silent period Tₛ. The first sensing signal may include a first sequence a₁. The first sequence a₁ may include two equal-length portions of sequence which are a first portion of sequence (i.e., sequence a_{1,1}) and a second portion of sequence (i.e., sequence a_{1,2}). The second sensing signal may include a sequence a₂. The sequence a₂ may include two equal-length portions of sequence which are a first portion of sequence (i.e., sequence a_{2,1}) and a second portion of sequence (i.e., sequence a_{2,2}). In some cases, sequence a_{1,1} and sequence a_{2,1} may be identical sequences. In some cases, sequence a_{2,2} may be a phase-inverted version of sequence a_{1,2} (i.e., −a_{1,2}).

In scenario 1000B, a sensing signal group may include a first sensing signal and a second sensing signal transmitted in pairs. A transmission of each sensing signal may be divided into a transmission period and a silent period. The first sensing signal may include a first sequence a′₁. The first sequence a′₁ may include two equal-length portions of sequence which are a first portion of sequence (i.e., sequence a′_{1,1}) and a second portion of sequence (i.e., sequence a′_{1,2}). The second sensing signal may include a sequence a′₂. The sequence a′₂ may include two equal-length portions of sequence which are a first portion of sequence (i.e., sequence a′_{2,1}) and a second portion of sequence (i.e., sequence a′_{2,2}). In some cases, sequence a′_{1,2} and sequence a′_{2,2} may be identical sequences. In some cases, sequence a′_{2,1} may be a phase-inverted version of sequence a′_{1,1} (i.e., −a_{1,1}).

In some cases, sequence a_{1,1} and sequence a_{1,2} (or sequence

$${a}_{1 , 1}^{′}$$

and sequence

$${a}_{1 , 2}^{′} )$$

may form a pair of complementary sequences with the same length H/2. As a result, the transmission of sequence a₁ and sequence a₂ (or the transmission of sequence a′ and pulse sequence

$${a}_{2}^{′} )$$

may form a pair of complementary sequences. This configuration may ensure that the sequences maintain the complementary property. The complementary sequences may satisfy the following equality:

$${R}_{{a}_{1 , 1} , {a}_{1 , 1}} ( τ ) + {R}_{{a}_{1 , 2} , {a}_{1 , 2}} ( τ ) = \{ \begin{matrix}H , & τ = 0 \\ 0 , & τ \neq 0\end{matrix}$$

$${R}_{{a}_{1 , 1}^{′} , {a}_{1 , 1}^{′}} ( τ ) + {R}_{{a}_{1 , 2}^{′} , {a}_{1 , 2}^{′}} ( τ ) = \{ \begin{matrix}H , & τ = 0 \\ 0 , & τ \neq 0\end{matrix}$$

$${R}_{{a}_{1} , {a}_{1}} ( τ ) + {R}_{{a}_{2} , {a}_{2}} ( τ ) = \{ \begin{matrix}2 H , & τ = 0 \\ 0 , & τ \neq 0\end{matrix}$$

$${R}_{{a}_{1}^{′} , {a}_{1}^{′}} ( τ ) + {R}_{{a}_{2}^{′} , {a}_{2}^{′}} ( τ ) = \{ \begin{matrix}2 H , & τ = 0 \\ 0 , & τ \neq 0\end{matrix}$$

where R_{XY}(τ) denotes the correlation function between sequences ‘X’ and ‘Y’ at time τ.

For the sensing signal group in scenario 1000A, when the target delay n_{τ} is less than H/2, the partially received signals of the sensing signal group may be phase-inverted and represented as p_{1,2} and p_{2,2} (i.e., −p_{1,2}). When

$$τ = {n}_{τ} + \frac{H}{2} ,$$

2N−1, the following equality may be satisfied:

$${R}_{{p}_{1 , 2} , {a}_{1}} ( τ ) + {R}_{{p}_{2 , 2} , {a}_{2}} ( τ ) = {R}_{{p}_{1 , 2} , {a}_{1 , 1}} ( τ ) + {R}_{( - {p}_{1 , 2} ) , {a}_{21}} ( τ ) = 0$$

This may indicate that, for targets in the minimum range (i.e., when n_{τ}≤H/2), the resulting sidelobe length in correlation processing may be H/2. The sequence a₁ may have a length of H, which may reduce the sidelobe range of the corresponding correlation function to H/2. As a result, sidelobes may be completely eliminated starting from H/2 points after the target delay. When the target delay H/2≤n_{τ}<H, the partially received signals of the sensing signal group may be represented as s₁ and s₂. When τ=H, . . . , n_{τ}+H−1, the following equality may be satisfied:

$${R}_{{s}_{1} , {a}_{1}} ( τ ) + {R}_{{s}_{2} , {a}_{2}} ( τ ) = {R}_{{a}_{1} , {a}_{1}} ( τ ) + {R}_{{a}_{2} , {a}_{2}} ( τ ) = 0$$

This may demonstrate that targets within the minimum range may exhibit no sidelobes after a time delay of H, indicating that the partially received signals may not affect the detection of targets outside the minimum range. When the target delay n_{τ}>H, the complete signal information of the transmitted waveform may be fully acquired. The following equality may be satisfied:

$${R}_{{a}_{1} , {a}_{1}} ( τ ) + {R}_{{a}_{2} , {a}_{2}} ( τ ) = 0 , τ \neq {n}_{τ} .$$

In scenario 1000B, the sensing signal group may exhibit correlation characteristics identical to those of the sensing signal group in scenario 1000A. This sequence configuration may ensure that, during correlation processing, sidelobes associated with targets within the minimum range may not extend beyond correlation point H, and that the length of sidelobes may be reduced to half the sequence length.

In some implementations, each sensing signal may include the first sequence and a second sequence. In particular, the first sequence may be transmitted by a first power, and the second sequence may be transmitted by a second power. The first power may be higher than the second power. In some cases, the first power may be configured for long-range detection. More specifically, the first power may be set to ensure sufficient transmission energy for detecting weak echoes from long-range targets. In some cases, the second power may be configured to be less than an ADC saturation power to prevent receiver saturation during the reception of echoes from short-range targets.

In some implementations, each second sequence may include: (1) a first portion of the second sequence, and (2) a second portion of the second sequence. The second sequence of the sensing signals may form a second complementary sequence set. The first portion of the second sequence and the second portion of the second sequence may be configured to suppress sidelobes of partially received signals.

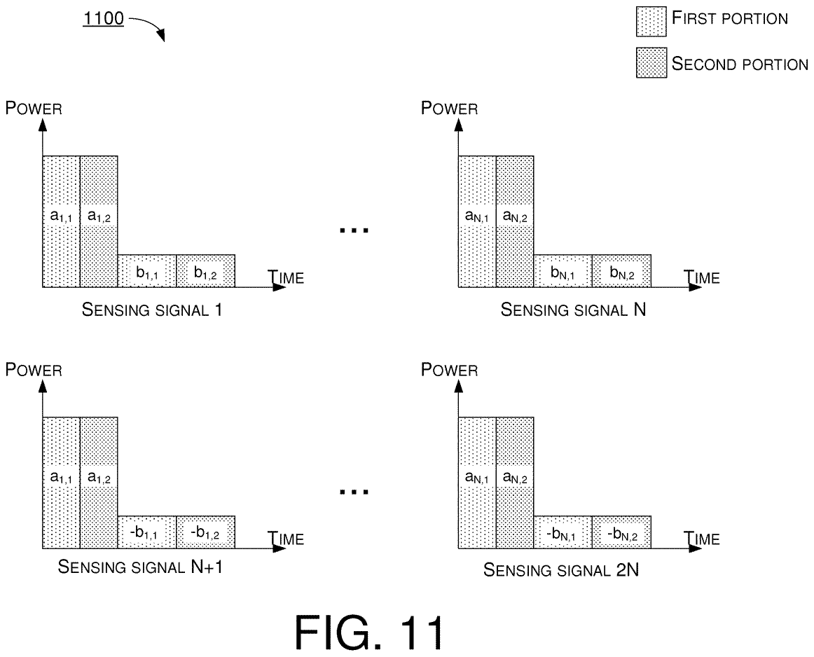

FIG. 11 illustrates an example scenario 1100 under schemes in accordance with implementations of the present disclosure. In some implementations, to suppress sidelobes of partially received signals, the sensing signals may be transmitted in groups. In particular, 2N sensing signals (or an integer multiple of 2N sensing signals) may be transmitted within one coherent processing interval, such that the N sensing signals appear as a group during coherent processing.

In some cases, the sensing signals generated from sequence set A may be transmitted at a high-power-level, where each sequence of length H is representable as a N×H matrix denoted as:

$$A = [ \begin{matrix}{a}_{1} \\ {a}_{2} \\ ⋮ \\ {a}_{N}\end{matrix} ]$$

where, an (1≤n≤N) denotes the n-th row sequence of A. a_{n,1} represents a first portion (e.g., points 1 to H/2) of sequence an, and a_{n,2} represents a second portion (e.g., points H/2+1 to H) of sequence aₙ.

In some cases, the sensing signals generated from sequence set B may be transmitted at a low-power-level, where each sequence of length L is representable as a N×L matrix denoted as:

$$B = [ \begin{matrix}{b}_{1} \\ {b}_{2} \\ ⋮ \\ {b}_{N}\end{matrix} ]$$

where, bₙ (1≤n≤N) denotes the n-th row sequence of B. b_{n,1} represents a first portion (e.g., points 1 to L/2) of sequence by, and b_{n,2} represents a second portion (e.g., points L/2+1 to L) of sequence bₙ. To suppress sidelobes from the target in the minimum range, transmitting sequence set A and sequence set B may satisfy the following equations:

$${\sum }_{n = 1}^{N} {R}_{{a}_{n} , {a}_{n}} ( τ ) = 0 , τ \neq 0$$

$${\sum }_{n = 1}^{N} {R}_{{b}_{n} , {b}_{n}} ( τ ) = 0 , τ \neq 0$$

$${\sum }_{n = 1}^{N} {R}_{{p}_{n , 1} , {a}_{n , 2}} = 0 , ∀ τ$$

$${\sum }_{n = 1}^{N} {R}_{{a}_{n , 1} , {p}_{n , 2}} = 0 , ∀ τ$$

where p_{n,1} denotes a partially received signal corresponding to sequence a_{n,1}, representing a portion of sequence a_{n,1} that the network node may sample. p_{n,2} denotes the partially received signal corresponding to sequence a_{n,2}.

During sensing operations utilizing partially received signals corresponding to low-power signals, sequence set B may satisfy the same mathematical constraints as sequence set A. When these conditions are satisfied, joint processing of the sensing signal group may reduce sidelobes of the partially received signals to half of the sequence length.

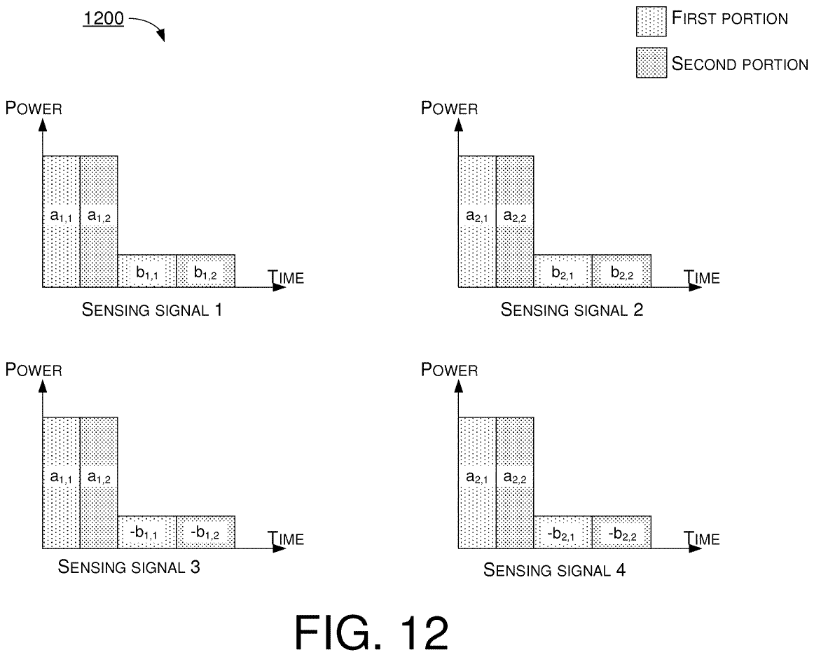

In some implementations, the plurality of sensing signals may include four sensing signals. FIG. 12 illustrates an example scenario 1200 under schemes in accordance with implementations of the present disclosure. In particular, the sequences of the sensing signals may require grouped transmission.

In scenario 1200, a sensing signal group may include a first sensing signal, a second sensing signal, a third sensing signal, and a fourth sensing signal. In the first sensing signal, a sequence transmitted at high-power-level may include a first portion of sequence (i.e., sequence a_{1,1}) and a second portion of sequence (i.e., sequence a_{1,2}), and a sequence transmitted at low-power-level may include a first portion of sequence (i.e., sequence b_{1,1}) and a second portion of sequence (i.e., sequence b_{1,2}). In some cases, sequence a_{1,1} may be complementary to sequence a_{1,2}. In some cases, sequence b_{1,1} may be complementary to sequence b_{1,2}.

In the second sensing signal, a sequence transmitted at the high-power-level may include a first portion of sequence (i.e., sequence a_{2,1}) and a second portion of sequence (i.e., sequence a_{2,2}), and a sequence transmitted at the low-power-level may include a first portion of sequence (i.e., sequence b_{2,1}) and a second portion of sequence (i.e., sequence b_{2,2}).

In some cases, sequence a_{2,1} may be identical to sequence a_{1,1}, and sequence a_{2,2} may be a phase-inverted version of sequence a_{1,2}. In some cases, sequence a_{2,1} may be a phase-inverted version of sequence a_{1,1}, and sequence a_{2,2} may be identical to sequence a_{1,2}.

In some cases, sequence b_{2,1} may be identical to sequence b_{1,1}, and sequence b_{2,2} may be a phase-inverted version of sequence b_{1,2}. In some cases, sequence b_{2,1} may be a phase-inverted version of sequence b_{1,1}, and sequence b_{2,2} may be identical to sequence b_{1,2}.

In the third sensing signal, a sequence transmitted at the high-power-level may include a first portion of sequence (i.e., sequence a_{1,1}) and a second portion of sequence (i.e., sequence a_{1,2}), and a sequence transmitted at the low-power-level may include a first portion of sequence (i.e., sequence—b_{1,1}) and a second portion of sequence (i.e., sequence—b_{1,1}).

In some cases, sequence—b_{1,1} may be a phase-inverted version of sequence b_{1,1}, and sequence—b_{1,2} may be a phase-inverted version of sequence b_{1,2}.

In the fourth sensing signal, a sequence transmitted at the high-power-level may include a first portion of sequence (i.e., sequence a_{2,1}) and a second portion of sequence (i.e., sequence a_{2,2}), and a sequence transmitted at the low-power-level may include a first portion of sequence (i.e., sequence—b_{2,1}) and a second portion of sequence (sequence—b_{2,2}).

In some cases, sequence—b_{2,1} may be a phase-inverted version of sequence b_{2,1} and sequence—b_{2,2} may be a phase-inverted version of sequence b_{2,2}. The sequence configuration requirements for eliminating sidelobes in partially received signals may be fully satisfied when sequences a_{1,1} and a_{1,2} form a complementary set and sequences b_{1,1} and b_{1,2} form another complementary set.

In some implementations, the first complementary sequence set of the first sequences of the sensing signals and a second complementary sequence set may be mutually orthogonal. In particular, the second complementary sequence set may be formed by sequences of other sensing signals, while the other sensing signals may be transmitted by the network node or another apparatus.

More specifically, to suppress inter-cell and intra-cell signal interference, sensing signal groups corresponding to different cells may be configured using mutually orthogonal complementary sequence sets. The cells may be associated with the same network node or different apparatus.

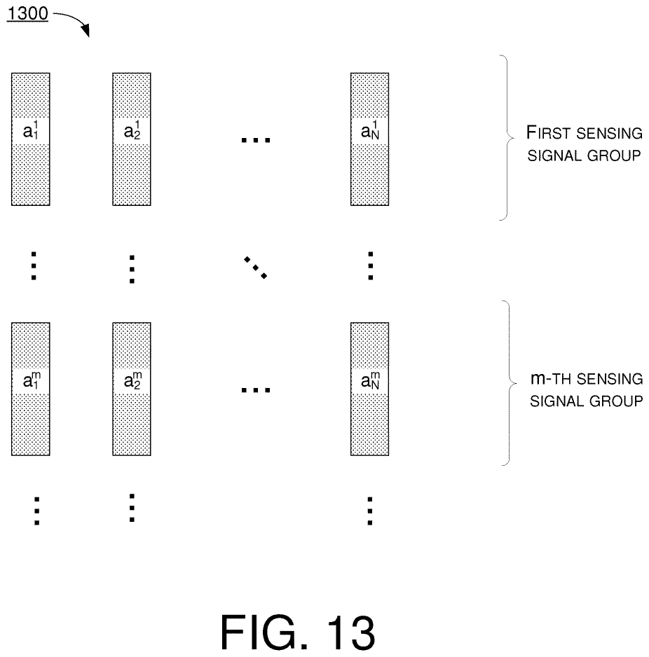

FIG. 13 illustrates an example scenario 1300 under schemes in accordance with implementations of the present disclosure. In some implementations, an SS may include N sequences of length H. Such a set may be denoted as (N, H)-SS and may be represented by an N×H matrix. Let A={A¹, A², . . . , A^{M}} denote a family of M matrices, each having a size N×H as:

$${A}^{m} = [ \begin{matrix}{a}_{1}^{m} \\ {a}_{2}^{m} \\ ⋮ \\ {a}_{N}^{m}\end{matrix} ]$$

where

$${a}_{n}^{m} ( 1 \leq n \leq N )$$

denotes the n-th row sequence of A^{m}. The family A may be a Mutually Orthogonal Complementary Sequence Set (MOCSS), denoted as (M, N, H)-MOCSS, when

$${R}_{{A}^{i} , {A}^{j}} ( τ ) = {\sum }_{n = 1}^{N} {R}_{{a}_{n}^{i} , {a}_{n}^{j}} ( τ ) = \{ \begin{matrix}NH , & i = j , τ = 0 \\ 0 , & otherwise\end{matrix}$$

where

$${R}_{{a}_{n}^{i} , {a}_{n}^{j}} ( τ )$$

denotes an aperiodic cross-correlation function between sequence

$${a}_{n}^{i}$$

and sequence

$${a}_{n}^{j} .$$

The sensing signal groups may be configured using (M, N, H)-MOCSS A={A¹, A², . . . , A^{M}}. The m-th sensing signal group may transmit continuous signals generated from sequence A^{m}.

In some cases, the m-th sensing signal group may include N sensing signals, representing an MOCSS configuration for the m-th cell. Such a configuration may be designated as orthogonal sensing signal groups. To achieve sidelobe cancellation in partially received signals, sequences

$${a}_{n , k}^{m} ( k = 1 , 2 )$$

may additionally satisfy the sequence configuration requirements illustrated in FIG. 9 and described in related paragraphs.

In some implementations, the first complementary sequence set of the first sequences of the sensing signals and a third complementary sequence set may be mutually orthogonal. The second complementary sequence set of the second sequences of the sensing signals and a fourth complementary sequence set may be mutually orthogonal. In particular, the third complementary sequence set and the fourth complementary sequence set may be respectively formed by sequences of other sensing signals, while the other sensing signals may be transmitted by the network node or another apparatus.

More specifically, to suppress inter-cell and intra-cell signal interference, sensing signal groups corresponding to different cells may be configured using mutually orthogonal complementary sequence sets. The cells may be associated with the same network node or different apparatus.

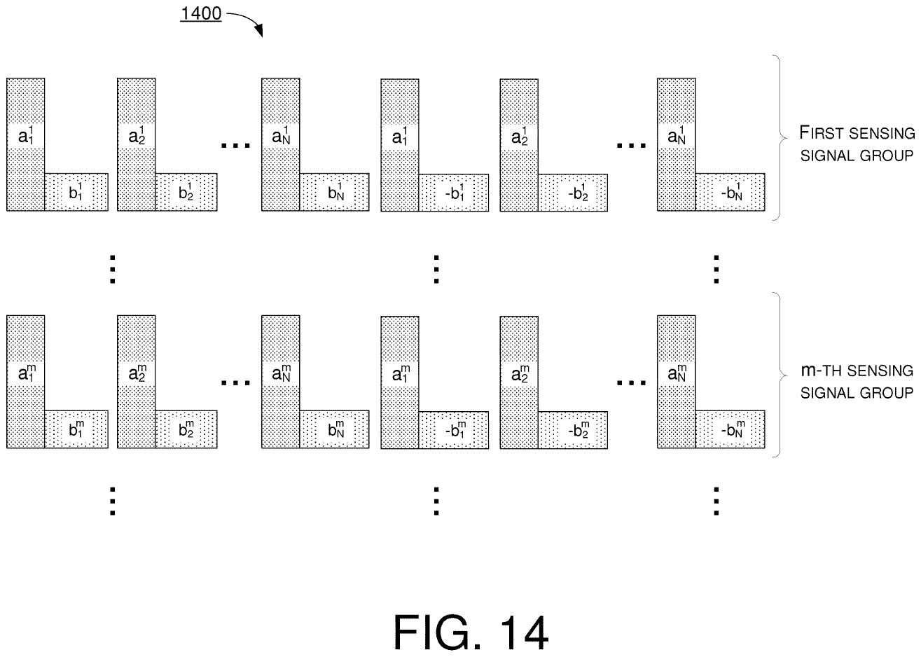

FIG. 14 illustrates an example scenario 1400 under schemes in accordance with implementations of the present disclosure. In some implementations, to suppress inter-cell and intra-cell signal interference, the sensing signal groups may be configured using (M, N,H)-MOCSS A={A¹, A², . . . , A^{M}} and (M, N, L)-MOCSS B={B¹, B², . . . , B^{M}}. The m-th sensing signal group may include 2N sensing signals, representing an MOCSS configuration for the m-th cell. For the latter N sensing signal configurations, a negation operation may need only to be applied to one sequence of each sensing signal pair and is not limited to the case illustrated in FIG. 14.

For example, the (N+1)-th sensing signal of the first cell may alternatively adopt the configuration

$$( - {a}_{1}^{1} , {b}_{1}^{1} ) .$$

This configuration may be designated as orthogonal sensing signal groups. To achieve sidelobe cancellation in partially received signals, sequences

$${a}_{n , k}^{m} and {b}_{n , k}^{m} ( k = 1 , 2 )$$

may additionally satisfy the sequence configuration requirements illustrated in FIG. 11 and described in related paragraphs.

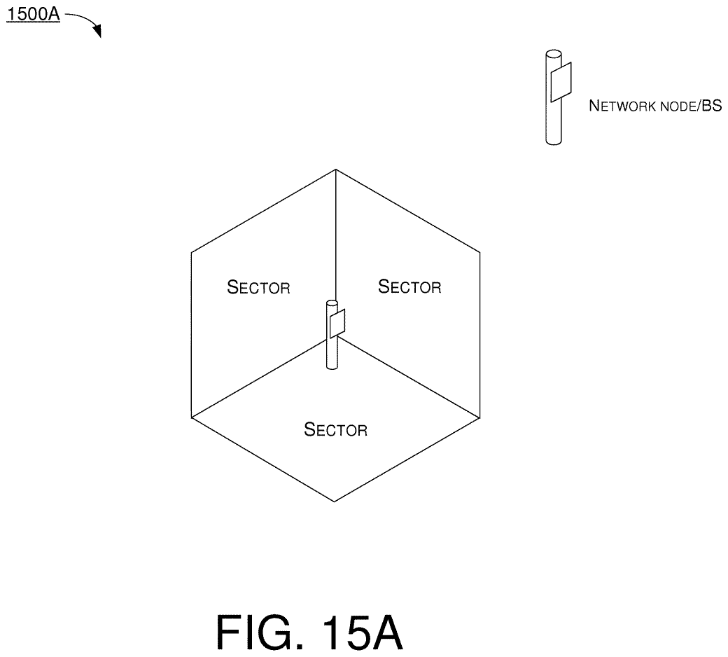

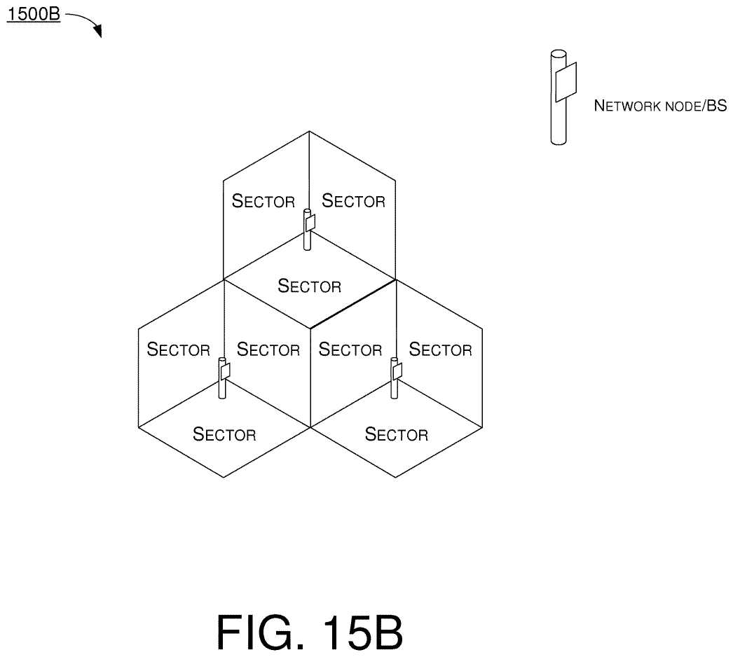

FIGS. 15A and 15B illustrate example scenarios 1500A and 1500B under schemes in accordance with implementations of the present disclosure. In some implementations, in a single-BS scenario 1500A, mutually orthogonal pulses or sensing signal groups may be employed across different sectors (e.g., cells) of the network node (e.g., a BS) to mitigate mutual interference among intra-cell sensing signals. In a multi-BS scenario 1500B, BSs may adopt the same configuration as the network node (e.g., one BS), thereby ensuring orthogonality between adjacent sectors and suppressing interference among sensing signals from different sectors. Accordingly, the network configuration may require at least three orthogonal pulses or sensing signal groups to support proper operation.

In some cases, the network configuration associated with the mutually orthogonal pulses or sensing signal groups may be determined by a centralized network node and provided by the centralized network node to the BSs. In some cases, the network configuration associated with the mutually orthogonal pulses or sensing signal groups may be determined by one of the BSs and provided by that BS to other BSs.

In some implementations, the network node of the present disclosure may include a transceiver. The transceiver of the network node may receive one or more reflections corresponding to one or more sensing signals (e.g., the previously sensing signals of the present disclosure). The one or more sensing signals may include a first sensing signal. The first sensing signal may include: (1) a first sequence transmitted by a first power, and (2) a second sequence transmitted by a second power. The first power is higher than the second power.

In some implementations, the transceiver may include a receiver. The receiver may include an antenna module, a Low Noise Amplifier (LNA) module, an ADC module, and a gain control module. The gain control module may be configured to control the gain of the LNA. In some cases, the gain control module may be configured to reduce the gain of the LNA during transmission of the first sequence and to increase the gain of the LNA during transmission of the second sequence.

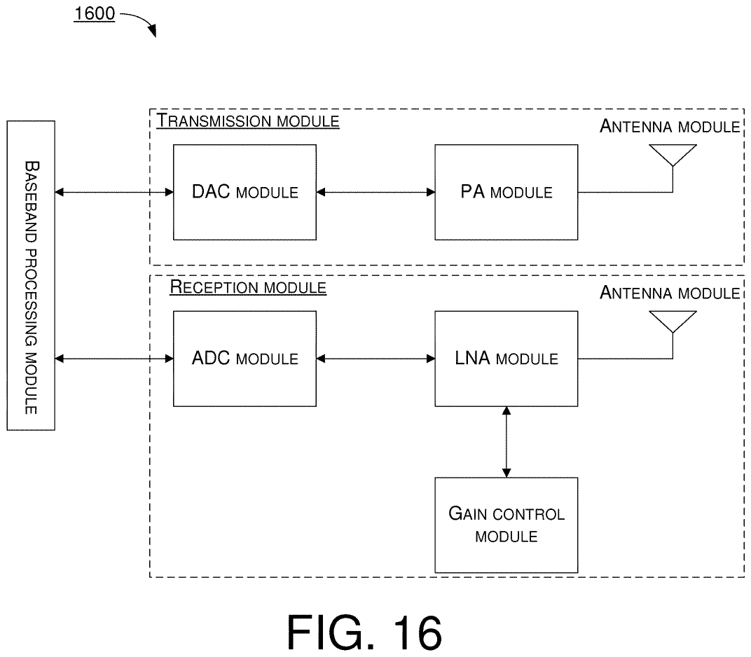

FIG. 16 illustrates an example scenario 1600 under schemes in accordance with implementations of the present disclosure. For example, the transceiver includes a baseband processing module, a transmission module, and a reception module. The baseband processing module is electrically coupled to the transmission module and the reception module.

The transmission module includes a Digital-to-Analog Converter (DAC) module and a Power Amplifier (PA) module, and the antenna module. The reception module includes the ADC module, the LNA module, the antenna module, and the gain control module. The gain control module is electrically coupled to the LNA module and configured to: (1) reduce the gain of the LNA during transmission of the first sequence, and (2) increase the gain of the LNA during transmission of the second sequence.

More specifically, the ADC module of the reception module requires a recovery period following saturation events. Accordingly, the gain control module applies a lower gain to prevent ADC saturation during high-power-level transmission. This approach may ensure that the ADC remains outside a recovery state during low-power-level transmission. During high-power-level transmission, the received signal exhibits strong self-interference and is therefore discarded during sensing processing. During low-power-level transmission, the gain control module applies a higher gain to reduce quantization noise in echo signals.

In some implementations, the transceiver may include a receiver. The receiver may include an antenna module, an LNA module, an ADC module, and a switch between the antenna module and the LNA module. In some cases, the switch may be configured to disconnect the antenna module from the LNA during transmission of the first sequence and to connect the antenna module to the LNA during transmission of the second sequence.

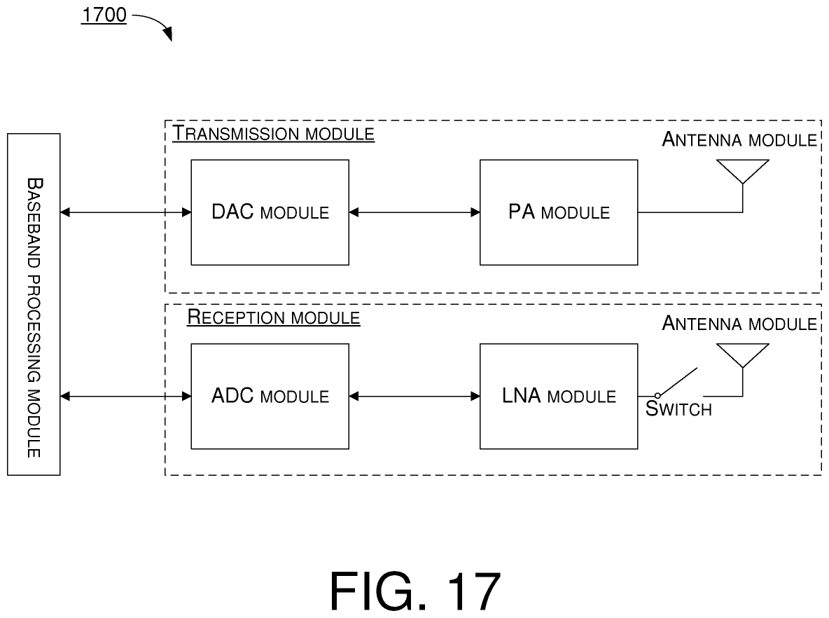

FIG. 17 illustrates an example scenario 1700 under schemes in accordance with implementations of the present disclosure. For example, the transceiver includes a baseband processing module, a transmission module, and a reception module. The baseband processing module is electrically coupled to the transmission module and the reception module.

The transmission module includes a DAC module, a PA module, and an antenna module. The reception module includes the ADC module, the LNA module, the antenna module, and the switch. The switch is set between the antenna module and the LNA module and configured to: (1) disconnect the antenna module from the LNA during transmission of the first sequence, and (2) connect the antenna module to the LNA during transmission of the second sequence.

More specifically, during high-power-level transmission, the switch remains open to prevent ADC saturation caused by self-interference. During low-power-level transmission, the switch closes while Automatic Gain Control (AGC) adjusts the receiver gain.

### Illustrative Implementations

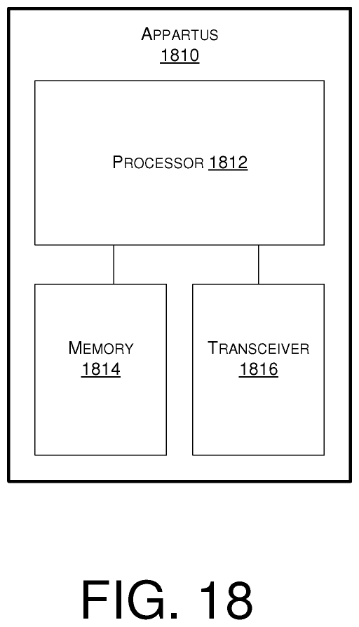

FIG. 18 illustrates an example apparatus 1810 in accordance with an implementation of the present disclosure. Apparatus 1810 may perform various functions to implement schemes, techniques, processes and methods described herein pertaining to signal design and sequence configuration in an ISAC system with respect to TX and RX in mobile communications, including scenarios/schemes described above as well as processes 1900 and 2000 described below.

Apparatus 1810 may be: (1) a part of an electronic apparatus, which may be a UE such as a portable or mobile apparatus, a wearable apparatus, a wireless communication apparatus or a computing apparatus, or (2) a part of a network apparatus, which may be a network node such as a satellite, a base station, a small cell, a router or a gateway. For instance, apparatus 1810 may be implemented in a smartphone, a smartwatch, a personal digital assistant, a digital camera, or a computing equipment such as a tablet computer, a laptop computer or a notebook computer. Apparatus 1810 may also be a part of a machine type apparatus, which may be an IoT, NB-IOT, or IIoT apparatus such as an immobile or a stationary apparatus, a home apparatus, a wire communication apparatus or a computing apparatus. For instance, apparatus 1810 may be implemented in a smart thermostat, a smart fridge, a smart door lock, a wireless speaker or a home control center. For instance, apparatus 1810 may be implemented in an eNodeB in an LTE network, in a gNB in a 5G/NR, IoT, NB-IOT or IIoT network or in a satellite or base station in a 6G network. Alternatively, apparatus 1810 may be implemented in the form of one or more integrated-circuit (IC) chips such as, for example and without limitation, one or more single-core processors, one or more multi-core processors, one or more reduced-instruction set computing (RISC) processors, or one or more complex-instruction-set-computing (CISC) processors. Apparatus 1810 may include at least some of those components shown in FIG. 18 such as a processor 1812, for example. Apparatus 1810 may further include one or more other components not pertinent to the proposed scheme of the present disclosure (e.g., internal power supply, display device and/or user interface device), and, thus, such component(s) of apparatus 1810 are neither shown in FIG. 18 nor described below in the interest of simplicity and brevity.

In one aspect, processor 1812 may be implemented in the form of one or more single-core processors, one or more multi-core processors, or one or more CISC processors. That is, even though a singular term “a processor” is used herein to refer to processor 1812, processor 1812 may include multiple processors in some implementations and a single processor in other implementations in accordance with the present disclosure. In another aspect, processor 1812 may be implemented in the form of hardware (and, optionally, firmware) with electronic components including, for example and without limitation, one or more transistors, one or more diodes, one or more capacitors, one or more resistors, one or more inductors, one or more memristors and/or one or more varactors that are configured and arranged to achieve specific purposes in accordance with the present disclosure. In other words, in at least some implementations, processor 1812 is a special-purpose machine specifically designed, arranged and configured to perform specific tasks including signal design and sequence configuration in an ISAC system in a device (e.g., as represented by apparatus 1810) in accordance with various implementations of the present disclosure.

In some implementations, apparatus 1810 may also include a transceiver 1816 coupled to processor 1812 and capable of wirelessly transmitting and receiving data. In other words, processor 1812 may transceive the data such as configuration, message, signal, information, indicator, etc. via transceiver 1816. In some implementations, apparatus 1810 may further include a memory 1814 coupled to processor 1812 and capable of being accessed by processor 1812 and storing data therein. Accordingly, apparatus 1810 may wirelessly communicate with other network nodes via transceiver 1816.

In some implementations, memory 1814 may include a type of random-access memory (RAM) such as dynamic RAM (DRAM), static RAM (SRAM), thyristor RAM (T-RAM) and/or zero-capacitor RAM (Z-RAM). Alternatively, or additionally, memory 1814 may include a type of read-only memory (ROM) such as mask ROM, programmable ROM (PROM), erasable programmable ROM (EPROM) and/or electrically erasable programmable ROM (EEPROM). Alternatively, or additionally, memory 1814 may include a type of non-volatile random-access memory (NVRAM) such as flash memory, solid-state memory, ferroelectric RAM (FeRAM), magnetoresistive RAM (MRAM) and/or phase-change memory.

### Illustrative Processes

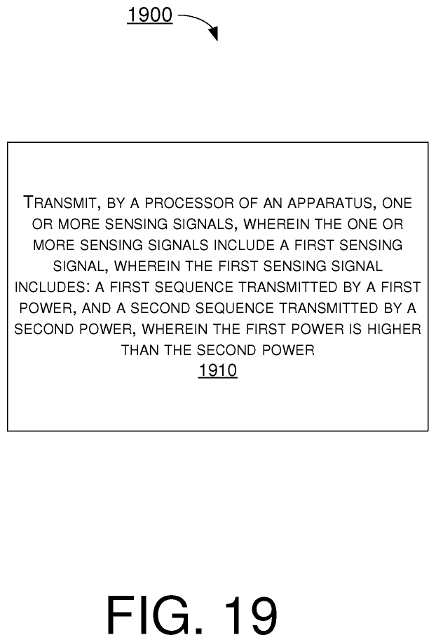

FIG. 19 illustrates an example process 1900 in accordance with an implementation of the present disclosure. Process 1900 may be an example implementation of above scenarios/schemes, whether partially or completely, with respect to signal design and sequence configuration in an ISAC system of the present disclosure. Process 1900 may represent an aspect of implementation of features of apparatus 1810 as both TX and RX in an ISAC system. Process 1900 may include one or more operations, actions, or functions as illustrated by one or more of block 1910. Although illustrated as discrete blocks, various blocks of process 1900 may be divided into additional blocks, combined into fewer blocks, or eliminated, depending on the desired implementation. Moreover, the blocks of process 1900 may be executed in the order shown in FIG. 19 or, alternatively, in a different order. Process 1900 may be implemented by both TX and RX such as apparatus 1810 or machine type devices. Solely for illustrative purposes and without limitation, process 1900 is described below in the context of apparatus 1810. Process 1900 may begin at block 1910.

At block 1910, process 1900 may involve processor 1812 of apparatus 1810 transmitting, via transceiver 1816, one or more sensing signals. The one or more sensing signals may include a first sensing signal. The first sensing signal may include: (1) a first sequence transmitted by a first power, and (2) a second sequence transmitted by a second power. The first power may be higher than the second power.

In some implementations, the first power may be configured for long-range detection, and the second power may be configured to be less than an ADC saturation power.

In some implementations, a transition period may be between the first sequence and the second sequence.

In some implementations, the one or more sensing signals may include a second sensing signal, and the second sensing signal may include: (1) a third sequence transmitted by the first power, and (2) a fourth sequence transmitted by the second power. The first sensing signal and the second sensing signal may be grouped based on a correlation property.

In some implementations, the first sequence and the third sequence may be complementary sequences, and the second sequence and the fourth sequence may be complementary sequences.

In some implementations, the one or more sensing signals may include a third sensing signal, and the third sensing signal includes: (1) a fifth sequence transmitted by the first power, and (2) a sixth sequence transmitted by the second power. The one or more sensing signals may include a fourth sensing signal, and the fourth sensing signal may include: (1) a seventh sequence transmitted by the first power, and (2) an eighth sequence transmitted by the second power. The first sensing signal, the second sensing signal, the third signal, and the fourth sensing signal may be grouped based on the correlation property.

In some implementations, the first sequence and the third sequence may be complementary sequences, the second sequence and the fourth sequence may be complementary sequences, the fifth sequence may be the same as the first sequence, the seventh sequence may be the same as the third sequence, the sixth sequence and the second sequence may be inverse sequences, and the eighth sequence and the fourth sequence may be inverse sequences.

In some implementations, process 1900 may involve processor 1812 of apparatus 1810 receiving, via transceiver 1816, a reflection of the one or more sensing signals from at least one target during a receiving window. The receiving window may include a sampling-off period corresponding to a period of transmitting the first sequence, the and a sampling-on period corresponding to a period of transmitting the second sequence.

In some implementations, the one or more sensing signals may be transmitted within at least one sensing symbol.

In some implementations, the at least one sensing symbol may be integrated into a TX-RX transition period.

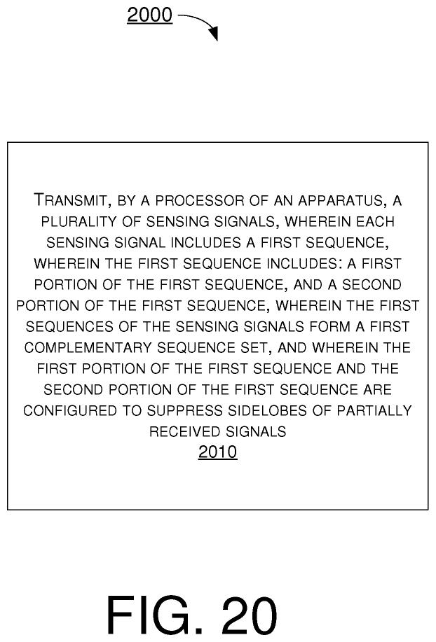

FIG. 20 illustrates an example process 2000 in accordance with an implementation of the present disclosure. Process 2000 may be an example implementation of above scenarios/schemes, whether partially or completely, with respect to signal design and sequence configuration in an ISAC system of the present disclosure. Process 2000 may represent an aspect of implementation of features of apparatus 1810 as both TX and RX in an ISAC system. Process 2000 may include one or more operations, actions, or functions as illustrated by one or more of block 2010. Although illustrated as discrete blocks, various blocks of process 2000 may be divided into additional blocks, combined into fewer blocks, or eliminated, depending on the desired implementation. Moreover, the blocks of process 2000 may be executed in the order shown in FIG. 20 or, alternatively, in a different order. Process 2000 may be implemented by both TX and RX such as apparatus 1810 or machine type devices. Solely for illustrative purposes and without limitation, process 2000 is described below in the context of apparatus 1810. Process 2000 may begin at block 2010.

At block 2010, process 2000 may involve processor 1812 of apparatus 1810 transmitting, via transceiver 1816, a plurality of sensing signals. Each sensing signal may include a first sequence. The first sequence may include: (1) a first portion of the first sequence, and (2) a second portion of the first sequence. The first sequences of the sensing signals may form a first complementary sequence set. The first portion of the first sequence and the second portion of the first sequence may be configured to suppress sidelobes of partially received signals.

In some implementations, the first complementary sequence set of the first sequences of the sensing signals and a second complementary sequence set may be mutually orthogonal, and the second complementary sequence set may be formed by sequences of other sensing signals.

In some implementations, each sensing signal may include a second sequence. The second sequence may include: (1) a first portion of the second sequence, and (2) a second portion of the second sequence. The second sequences of the sensing signals may form a second complementary sequence set. The first portion of the second sequence and the second portion of the second sequence may be configured to suppress sidelobes of partially received signals.

In some implementations, the first complementary sequence set of the first sequences of the sensing signals and a third complementary sequence set may be mutually orthogonal, the second complementary sequence set of the second sequences of the sensing signals and a fourth complementary sequence set may be mutually orthogonal, and the third complementary sequence set and the fourth complementary sequence set may be respectively formed by sequences of other sensing signals.

In some implementations, the first sequences may be transmitted by a first power, the second sequences may be transmitted by a second power, and the first power may be higher than the second power.

### Additional Notes

The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

What is claimed is:

1. A method, comprising:
transmitting, by a processor of an apparatus, one or more sensing signals, wherein the one or more sensing signals include a first sensing signal, wherein the first sensing signal includes:
a first sequence transmitted by a first power, and
a second sequence transmitted by a second power,
wherein the first power is higher than the second power.

2. The method of claim 1, wherein the first power is configured for long-range detection, and the second power is configured to be less than an Analog-Digital Converter (ADC) saturation power.

3. The method of claim 1, wherein a transition period is between the first sequence and the second sequence.

4. The method of claim 1, wherein the one or more sensing signals include a second sensing signal, and the second sensing signal includes:
a third sequence transmitted by the first power, and
a fourth sequence transmitted by the second power,
wherein the first sensing signal and the second sensing signal are grouped based on a correlation property.

5. The method of claim 4, wherein the first sequence and the third sequence are complementary sequences, and the second sequence and the fourth sequence are complementary sequences.

6. The method of claim 4, wherein the one or more sensing signals include a third sensing signal, and the third sensing signal includes:
a fifth sequence transmitted by the first power, and
a sixth sequence transmitted by the second power,
wherein the one or more sensing signals include a fourth sensing signal, and the fourth sensing signal includes:
a seventh sequence transmitted by the first power, and
an eighth sequence transmitted by the second power,
wherein the first sensing signal, the second sensing signal, the third signal, and the fourth sensing signal are grouped based on the correlation property.

7. The method of claim 6, wherein the first sequence and the third sequence are complementary sequences, the second sequence and the fourth sequence are complementary sequences, and
the fifth sequence is the same as the first sequence, the seventh sequence is the same as the third sequence, the sixth sequence and the second sequence are inverse sequences, and the eighth sequence and the fourth sequence are inverse sequences, or
the fifth sequence and the first sequence are inverse sequences, the seventh sequence and the third sequence are inverse sequences, the sixth sequence is the same as the second sequence, and the eighth sequence is the same as the fourth sequence.

8. The method of claim 1, further comprising:
receiving, by the processor, a reflection of the one or more sensing signals from at least one target during a receiving window, wherein the receiving window includes a sampling-off period corresponding to a period of transmitting the first sequence, and a sampling-on period associated with a period of transmitting the second sequence.

9. The method of claim 1, wherein the one or more sensing signals are transmitted within at least one sensing symbol.

10. The method of claim 9, wherein the at least one sensing symbol is integrated into a Transmission-Reception (TX-RX) transition period.

11. A method, comprising:
transmitting, by a processor of an apparatus, a plurality of sensing signals, wherein each sensing signal includes a first sequence,
wherein the first sequence includes:
a first portion of the first sequence, and
a second portion of the first sequence,
wherein the first sequences of the sensing signals form a first complementary sequence set, and
wherein the first portion of the first sequence and the second portion of the first sequence are configured to suppress sidelobes of partially received signals.

12. The method of claim 11, wherein the first complementary sequence set of the first sequences of the sensing signals and a second complementary sequence set are mutually orthogonal, and the second complementary sequence set is formed by sequences of other sensing signals.

13. The method of claim 11, wherein each sensing signal includes a second sequence, and the second sequences of the sensing signals form a second complementary sequence set.

14. The method of claim 13, wherein the second sequence includes:
a first portion of the second sequence, and
a second portion of the second sequence,
wherein the first portion of the second sequence and the second portion of the second sequence are configured to suppress sidelobes of partially received signals.

15. The method of claim 14, wherein the first complementary sequence set of the first sequences of the sensing signals and a third complementary sequence set are mutually orthogonal, the second complementary sequence set of the second sequences of the sensing signals and a fourth complementary sequence set are mutually orthogonal, and the third complementary sequence set and the fourth complementary sequence set are respectively formed by sequences of other sensing signals.

16. An apparatus, comprising:
a transceiver which, during operation, wirelessly communicates with a wireless network; and
a processor communicatively coupled to the transceiver such that, during operation, the processor performs operations comprising:
receiving, via the transceiver, one or more reflections corresponding to one or more sensing signals, wherein the one or more sensing signals include a first sensing signal,
wherein the first sensing signal includes:
a first sequence transmitted by a first power, and
a second sequence transmitted by a second power,
wherein the first power is higher than the second power.

17. The apparatus of claim 16, wherein the transceiver includes a receiver, the receiver includes an antenna module, a Low Noise Amplifier (LNA) module, an Analog-to-Digital Converter (ADC) module, and a gain control module, and the gain control module is configured to control a gain of the LNA module.

18. The apparatus of claim 17, wherein the gain control module is configured to reduce the gain of the LNA module during transmission of the first sequence and to increase the gain of the LNA module during transmission of the second sequence.

19. The apparatus of claim 16, wherein the transceiver includes a receiver, the receiver includes an antenna module, a Low Noise Amplifier (LNA) module, an Analog-to-Digital Converter (ADC) module, and a switch between the antenna module and the LNA module.

20. The apparatus of claim 19, wherein the switch is configured to disconnect the antenna module from the LNA module during transmission of the first sequence and to connect the antenna module to the LNA module during transmission of the second sequence.
